(19) United States
(12) Patent Application Publication
(10) Pub. No.: US 2009/0002059 A1
(43) Pub. Date: Jan. 1, 2009

(54) Rail to rail full complementary CMOS isolation gate

(76) Inventor: Kwang Tatt Loo, Penang (MY)

Correspondence Address: LAW OFFICE OF DONALD D. MONDUL;c/o INTELLEVATE, P.O. BOX 52050, MINNEAPOLIS, MN, 55402, US

(21) Appl. No.: 11/823,974

(22) Filed: Jun. 29, 2007

(51) Int. Cl. G11C 5/14

(52) U.S. Cl. 327/530

(57) ABSTRACT

An isolation gate to provide isolation to a circuit to be isolated for a first voltage and a second voltage includes a voltage source for the first voltage and the second voltage, a first path coupled to the circuit to be isolated and a first control switch to control the first path. The first control switch isolates the circuit to be isolated while said isolation gate is subject to either the first voltage or the second voltage.

### FILED

The present isolation gate circuit relates to a dual voltage isolation gate circuit.

### BACKGROUND

The manufacture and design of integrated circuits has greatly increased in sophistication, including the need for the isolation of gate conductors.

### BRIEF DESCRIPTION OF THE DRAWING

FIG. 1 illustrates a circuit diagram.

### DETAILED DESCRIPTION

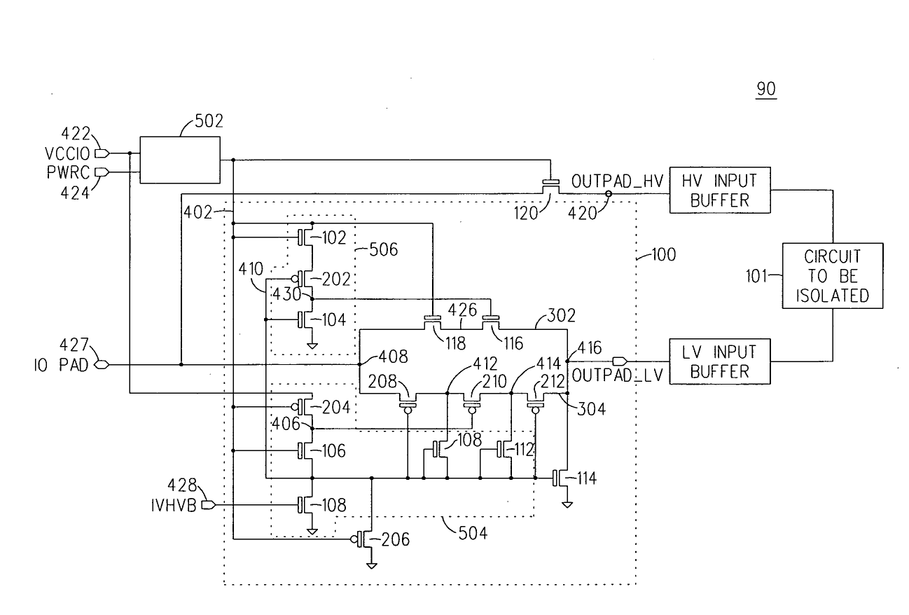

FIG. 1 illustrates a circuit 100 which may be an isolation gate circuit to isolate a circuit to be isolated such as a core logic or other types of logic and may include a first terminal 402. First terminal 402 may be coupled to a drain and gate of a n type field effect transistor NFET 102 and coupled to the gate of a NFET 120. First terminal 402 may be additionally coupled to the gate of a PFET 204, to the gate of a NFET 106, to the gate of a PFET 206 and to the gate of a NFET 118.

The source of NFET 102 may be coupled to the source of a p type field effect transistor PFET 202, and the drain of PFET 202 may be coupled to the drain of a NFET 104. The source of NFET 104 may be coupled to ground, and the gate of PFET 202 and the gate of NFET 104 may be coupled to terminal 410.

Terminal 410 may be coupled to the source of NFET 106, the drain of NFET 108, the source of PFET 206, the gate of PFET 208, the gate and source of NFET 110, the gate and source of NFET 112, the gate of PFET 212 and a gate of NFET 114.

A first path 302 may include a NFET 116 and a NFET 118; NFET 116 and NFET 118 may be formed in series and may have a drain of NFET 118 coupled to a source of NFET 116. The gate of NFET 116 may be coupled to the drain of PFET 202 and the drain of NFET 104 and the gate of NFET 118 may be coupled to terminal 402. The drain of NFET 116 may be coupled to terminal 416, and the source of NFET 118 may be coupled to a terminal 408.

A first biasing circuit 506 may control the biasing of path 302. More particularly, the gate of NFET 118 may be connected to the drain of NFET 102 and to terminal 402. NFET 118 and NFET 116 may be a control switch for path 302. Other types of transistors including bipolar transistors may be employed as the first and second control switch. The gate of NFET 116 may be connected to the drain of PFET 202 and may be connected to the drain of NFET 104.

A second path 304 may include a PFET 208, a PFET 210 and a PFET 212 which may have a drain coupled to a terminal 416 and which may have a source coupled to the drain of PFET 210. PFET 208, PFET 210 and PFET 212 may be another control switch to control path 304. Other transistors including bipolar transistors may be employed as the third, fourth and fifth control switches. PFET 208, PFET 210 and PFET 212 may be in series. PFET 210 may have a source connected to the drain of PFET 208, and the source of PFET 208 may be coupled to terminal 408 which may be connected to the I/O pad at a terminal 427 and which may be coupled to the source of NFET 120.

The drain of NFET 110 may be connected to the source of PFET 210, and the drain of NFET 112 may be connected to the source of PFET 212.

A bias circuit 504 may include PFET 204, NFET 106, NFET 108, NFET 110 and NFET 112.

The gate of PFET 208 may be connected to the terminal 410; the gate of PFET 210 may be connected to the drain of PFET 204 and connected to the drain of NFET 106.

The gate of PFET 212 may be connected to terminal 410.

The high-voltage input buffer at terminal 420 may be coupled to the drain of NFET 120 while the source of NFET 120 may be coupled to the input/output I/O pad at terminal 427.

A low voltage input buffer may be coupled to terminal 416 and may be controlled by path 302 and path 304.

FIG. 1 illustrates a voltage circuit 502 which may be controlled by a first input at terminal 422 and a second input at a terminal 424. The output of the voltage circuit 502 may be connected to terminal 402. When the voltage at the first input at terminal 422 is a first input voltage which may be 3.3 volts V, the output of the voltage circuit is a first output voltage which may be 2.5 V at terminal 402. When the voltage at the first input at terminal 422 is a second voltage which may be 1.5 V, the output of the voltage circuit is a second output voltage, which may be 1.5 volts.

PFET 206 is a leaker device that stabilizes the voltage at terminal 410 and NFET 114 ensures that the voltage at terminal 416 is zero when the isolation gate is shut off.

When terminal 422 which is input to the voltage circuit is at approximately 3.3 V during a 3.3 V signaling environment, the voltage at terminal 402 may be approximately 2.5 V and the voltage at terminal 428 may be approximately 0 V. Under these conditions, the isolation gate 100 may be expected to be shut off in order to isolate the voltage at terminal 416 in order to isolate terminal 416 from the I/O pad. Under these conditions, NFET 116 may be shut off and NFET 118 may be turned on.

The net voltage at terminal 426 may range between zero and 2.5-Vt voltage threshold while the voltage at the I/O pad may swing between zero and approximately 3.3 V. The voltage drain to source Vds, voltage gate to drain Vgd and voltage gate to source Vgs of both NFET 116 and NFET 118 may be less than 2.5 V, and consequently, these devices may be electrical overvoltage stress EOS safe. Since NFET 116 is off, path 302 may be disabled. Additionally, terminal 406 in terminal 410 may be biased at 3.3 V and 2.5-Vt, respectively. Terminal 414 may be biased at 2.5-2 Vt by NFET 112. PFET 210 and PFET 212 may be shut off as a result of this biasing. The output at terminal 416 of the isolation gate is pulled low by NFET 114. The voltage at terminal 412 may range from 2.5-2 Vt to 3.3V when the I/O pad at terminal 427 swings between 0 to 3.3 V. Vgs, Vgd and Vds may be less than 2.5 V and therefore may be EOS safe. Path 304 may be disabled as a possible result of PFET 210 and PFET 212 being shut off. With path 302 and path 304 are both disabled, the isolation gate may be completely tri-stated.

For 1.5 signaling, terminal 422 may be at 1.5 V. NFET 108 may be turned on by the voltage at terminal 428. As a result, the net voltage at terminal 406 and terminal 410 may both be pulled low. PFET 204 may be shut off because the voltage at terminal 402 may be 1.5 V while the voltage at terminal 422 may be also 1.5 V. NFET 106 may be turned on. The gates of PFET 208, PFET 210 and PFET 212 may be all biased to 0 V. Path 304 may be formed between terminal 416 and terminal 426. At the same time, NFET 116 and NFET 118 may be both turned on since the net voltage of terminal 430 is biased at 1.5-Vt and NFET 118 may be turned on. As a result, the path 302 may be established. Consequently, both path 302 and path 304 may be enabled allowing full rail to rail signal transmission through the isolation gate. Terminal 420 may be connected to the high-voltage HV Input Buffer of a core logic circuit or other type of logic circuit (not shown in FIG. 1) and terminal 416 may be connected to the low voltage LV Input Buffer of a core logic circuit or other type of logic circuit (not shown in FIG. 1). The following summarizes the state of most of the devices in the isolation gate based on this 3.3/1.5 signaling.

The First Case

When the voltage at terminal 422 may be 3.3 volts, the voltage at terminal 428 may be zero and the voltage at terminal 427 may be 0 V, the voltage at 402 may be 2.5 V, the voltage at terminal 406 may be 3.3 V, the voltage at terminal 410 may be 2.5-Vt, the voltage at terminal 412 may be 2.5-2* Vt, the voltage at terminal 414 may be 2.5-2* Vt, PFET 204 may be on, NFET 106 may be on, NFET 108 may be off, PFET 208 may be off, PFET 210 may be off, PFET 212 may be off, NFET 114 may be on and the voltage at terminal 416 may be zero.

FET 102 may be on, PFET 202 may be off, NFET 104 may be on, the voltage at terminal 430 may be zero, the voltage at terminal 426 may be zero, NFET 116 may be off and NFET 118 may be on.

The Second Case

When the when the voltage at terminal 422 may be 3.3 volts, the voltage at terminal 428 may be zero and the voltage at terminal 427 may be 3.3 V, the voltage at terminal 402 may be 2.5 V, the voltage at terminal 406 may be 3.3 V, the voltage at terminal 410 may be 2.5-Vt, the voltage at terminal 412 may be 3.3 V, the voltage at terminal 414 may be 2.5-2* Vt, PFET 204 may be on, NFET 106 may be on, NFET 108 may be off, PFET 208 may be on, PFET 210 may be off, PFET 212 may be off, NFET 114 may be on and the voltage at terminal 416 may be zero.

FET 102 may be on, PFET 202 may be off, NFET 104 may be on, the voltage at terminal 430 may be zero, the voltage at terminal 426 may be 2.5-Vt, NFET 116 may be off and NFET 118 may be on.

The Third Case

When the voltage at terminal 422 may be 1.5 volts, the voltage at terminal 428 may be 1.1 and the voltage at terminal 427 may be zero, the voltage at terminal 402 may be 1.5 V, the voltage at terminal 406 may be 0 V, the voltage at terminal 410 may be 0V, PFET 204 may be off, NFET 106 may be on, NFET 108 may be on, PFET 208 may be off, PFET 210 may be off, PFET 212 may be off, NFET 114 may be off and the voltage at terminal 416 may be zero.

FET 102 may be on, PFET 202 may be on, NFET 104 may be off, the voltage at terminal 430 may be 1.5-Vt, the voltage at terminal 426 may be 0, NFET 116 may be on and NFET 118 may be on.

The Fourth Case

When the when the voltage at terminal 422 may be 1.5 volts, the voltage at terminal 428 may be 1.1 and the voltage at terminal 427 may be 1.5 V, the voltage at terminal 402 may be 1.5 V, the voltage at terminal 406 may be 0 V, the voltage at terminal 410 may be 0V, the voltage at terminal 412 may be 1.5 V, the voltage at terminal 414 may be 1.5 V, PFET 204 may be off, NFET 106 may be on, NFET 108 may be on, PFET 208 may be on, PFET 210 may be on, PFET 212 may be on, NFET 114 may be off and the voltage at terminal 416 may be 1.5V.

FET 102 may be on, PFET 202 may be on, NFET 104 may be off, the voltage at terminal 430 may be 1.5-Vt, the voltage at terminal 426 may be 1.5-Vt, NFET 116 may be on and NFET 118 may be on.

FIG. 1 additionally illustrates system 90 which includes the isolation gate 100 and the circuit to be isolated 101.

This circuit can be instantiated in the dual voltage IO where the input buffer can be isolated as desired. It allows multiple input buffers with different input characteristics to co-exist in the same IO pin out. Multiple input buffer designs can be multiplexed into the same pin out and saves package pin count.

In order to facilitate the 10 voltage roadmap transition from 3.3V to 1.5V, a combination IO (3.3V/1.5V) buffer is needed to enable the vendor to develop new applications with the low voltage IO while still supporting the high voltage IO application. During this transition, 3.3V and 1.5V signaling support must co-exist and the isolation gate would allow the implementation of both the 3.3V and 1.5V input buffer at the same pin out in 2.5V CMOS process without any risk of electrical overstress. Moreover, the isolation gate swings rail to rail and it has the ability to support any CMOS input buffer with high trip point.

1) An apparatus, comprising:
a circuit to be isolated from a first voltage and the second voltage,
a voltage source for the first voltage and the second voltage;
an isolation gate, including:
a first path coupled to the a low voltage buffer of a circuit to be isolated;
a first control switch to control the first path;
wherein the first control switch is operable to continuously isolate the low voltage buffer of the circuit to be isolated while said isolation gate is subject to the first voltage and operable to controllably isolate the low voltage buffer of the circuit to be isolated while said isolation gate is subject to the second voltage.

2) An apparatus as in claim 1, wherein said isolation gate includes a second path coupled to the circuit to be isolated and a second control switch to control the second path wherein the second control switch is operable to isolate the circuit to be isolated while the isolation gate is subject to one of the first voltage or the second voltage.

3) An apparatus as in claim 1, wherein the isolation gate includes a first bias circuit to bias the first control circuit.

4) An apparatus as in claim 1, wherein the isolation gate is operable to isolate an I/O pad from the circuit to be isolated.

5) An apparatus as in claim 1, wherein the isolation gate is operable to isolate an I/O pad from a voltage input buffer.

6) An apparatus as in claim 1, wherein the voltage input buffer may be a low voltage input buffer.

7) A system, comprising:
a voltage source for the first voltage and the second voltage; and
an isolation gate to provide isolation to a circuit to be isolated from a first voltage and a second voltage, including;
a first path coupled to the circuit to be isolated;
a first control switch to control the first path;
wherein the first control switch is operable to continuously isolate a low voltage buffer of the circuit to be isolated while said isolation gate is subject to the first voltage and operable to controllably isolate the low voltage buffer of the circuit to be isolated while said isolation gate is subject to the second voltage.

8) A system as in claim 7, wherein said isolation gate includes a second path coupled to the circuit to be isolated and a second control switch to control the second path wherein the second control switch is operable to isolate the circuit to be isolated while the isolation gate is subject to one of the first voltage or the second voltage.

9) An apparatus as in claim 7, wherein the isolation gate includes a first bias circuit to bias the first control circuit.

10) An apparatus as in claim 7, wherein the isolation gate is operable to isolate an I/O pad from the circuit to be isolated.

11) An apparatus as in claim 7, wherein the isolation gate is operable to isolate an I/O pad from a voltage input buffer.

12) An apparatus as in claim 7, wherein the voltage input buffer may be a low voltage input buffer.
